(19) United States
(12) Patent Application Publication
(10) Pub. No.: US 2011/0280269 A1
(43) Pub. Date: Nov. 17, 2011

(54) HIGH CONTRAST GRATING INTEGRATED VCSEL USING ION IMPLANTATION

(75) Inventors: Connie Chang-Hasnain, Palo Alto, CA (US); Christopher Chase, Kensington, CA (US); Yi Rao, Berkeley, CA (US)

(73) Assignee: THE REGENTS OF THE UNIVERSITY OF CALIFORNIA, Oakland, CA (US)

(21) Appl. No.: 12/779,248

(22) Filed: May 13, 2010

(51) Int. Cl. H01S 5/026

(52) U.S. Cl. 372/50.1

(57) ABSTRACT

A Vertical Cavity Surface Emitting Laser (VCSEL) and its fabrication are taught which incorporate a high contrast grating (HCG) to replace the top mirror of the device and which can operate at long-wavelengths, such as beyond 0.85 μm. The HCG beneficially provides a high degree of polarization differentiation and provides optical containment in response to lensing by the HCG. The device incorporates a quantum well active layer, a tunnel junction, and control of aperture width using ion implantation. A tunable VCSEL is taught which controls output wavelength in response to controlling a micro-mechanical actuator coupled to a HCG top mirror which can be moved to, or from, the body of the VCSEL. A fabrication process for the VCSEL includes patterning the HCG using a wet etching process, and highly anisotropic wet etching while precisely controlling temperature and PH.

### CROSS-REFERENCE TO RELATED APPLICATIONS

Not Applicable

### STATEMENT REGARDING FEDERALLY SPONSORED RESEARCH OR DEVELOPMENT

Not Applicable

### INCORPORATION-BY-REFERENCE OF MATERIAL SUBMITTED ON A COMPACT DISC

Not Applicable

### NOTICE OF MATERIAL SUBJECT TO COPYRIGHT PROTECTION

A portion of the material in this patent document is subject to copyright protection under the copyright laws of the United States and of other countries. The owner of the copyright rights has no objection to the facsimile reproduction by anyone of the patent document or the patent disclosure, as it appears in the United States Patent and Trademark Office publicly available file or records, but otherwise reserves all copyright rights whatsoever. The copyright owner does not hereby waive any of its rights to have this patent document maintained in secrecy, including without limitation its rights pursuant to 37 C.F.R. §1.14.

### BACKGROUND OF THE INVENTION

1. Field of the Invention

This invention pertains generally to VCSELS, and more particularly to high contrast gratings incorporated within VCSELs.

2. Description of Related Art

Vertical cavity surface emitting lasers (VCSELs) are a very promising low cost laser source for numerous application areas, including metro area access networks, PON applications, and diode laser spectroscopy. In particular, VCSELs emitting in the 1.3 to 1.6 μm wavelength range are of interest for long-reach optical interconnects and optical fiber communications.

However, long-wavelength VCSELs pose numerous fabrication challenges in comparison to GaAs-based short-wavelength VCSELs. One of the challenges is that of forming a current aperture in the Indium Phosphide (InP) based material system. Yet, each of these approaches is technically complex and presents major obstacles to the manufacture of low cost long-wavelength VCSELs.

An additional problem with fabricating long-wavelength VCSELs is that of fabricating a p-side mirror on the VCSEL. It is quite difficult to grow a p-doped distributed Bragg reflector (DBR) on Indium Phosphide (InP), which is a preferred VCSEL substrate material, because its free-carrier absorption is very significant at telecommunications wavelengths (approximately 1.3 to 1.6 μm) resulting in a top mirror which is extremely lossy when formed in p-material. To further complicate the problem, the index contrast available in the material system lattice-matched to InP is relatively small. This small index contrast results in the need of at least 40 pairs of epitaxial DBR for both bottom and top of the VCSEL structure, which is such a challenging technological proposition that it has not been realized as of this writing.

Alternative approaches have been considered to overcome these problems in fabricating a p-side mirror in a VCSEL structure. One approach is the forming of a short current spreading p-region, or alternatively a buried tunnel junction with n-region, followed by incorporating intra-cavity contacts. The top mirror is then formed by either evaporating a dielectric mirror, or wafer fusion of an epitaxially grown DBR on another material system. These options are technologically challenging and costly compared to using a mirror that is already contained in the underlying epitaxial structure, as is used in a GaAs-based VCSEL.

Accordingly, a need exists for a vertical cavity laser (VCSEL) apparatus and associated methods for simplifying fabrication. These needs and others are met within the present invention, which overcomes the deficiencies of previously developed VCSEL apparatus and fabrication methods.

### BRIEF SUMMARY OF THE INVENTION

The present invention provides a number of novel teachings for use in fabricating long-wavelength VCSELs and their p-side mirrors and current confinement technique. These teachings include use and fabrication of a high contrast grating (HCG) as a top mirror, and mechanisms of forming a current aperture and toward removing most p-doped materials by inserting a tunnel junction near the active region, which allows most p-materials to be replaced by n-materials.

Considering VCSEL mirror fabrication, the inventors have found that a High Contrast Grating (HCG) can totally replace the top DBR in a VCSEL. The HCG is a grating having subwavelength dimensions comprising high index bars completely surrounded by a low-index media, such as oxide or air. It is the width of the bars and their respective periodicity which are configured at subwavelength dimensions. It should be appreciated that an HCG provides intrinsic polarization control to VCSELs, which has been highly sought after, but was previously very difficult to implement. Long wavelength VCSEL devices according to the invention can be utilized in a wide range of applications, including but not limited to: data communication sources, Passive Optical Networks (PONS), active optical cable, access networks, diode laser spectroscopy and so forth.

When integrated on a wavelength tunable VCSEL, a tuning speed can be achieved which is vastly increased due to the small mass of the HCG compared to the conventional DBR. In addition, HCGs can be leveraged to make controllably defined arrays of VCSELs operating at different wavelengths for use in applications such as wavelength division multiplexing, data communications, low cost tunable laser sources (e.g., spectroscopy, biological sensing), and so forth.

HCG VCSELs have been demonstrated operating at a wavelength of 850 nm on a GaAs-based platform, however, using the GaAs material platform it is extremely difficult to produce VCSELs beyond 1.3 μm. As already mentioned, there are many potential applications for VCSELs in next generation access networks and passive optical networks (PONS) which require VCSEL operation beyond 1.3 μm, such as at 1.55 μm. Use of the InP material system should be the system of choice for fabricating 1.55 μm VCSELs, because of its commercially-proven active region operating at 1.55 μm.

The first HCG VCSELs operating on an InP platform at 1.34 μm were fabricated by the inventors, but initially operated only in pulsed mode at room temperature, and continuous-wave at slightly less than room temperature. It was found that the sub-optimal performance arose in response to large mismatches between the VCSEL cavity wavelength and optical gain wavelength. The teachings of the present invention describe a 1.55 μm HCG VCSEL fabricated on an InP platform which provides continuous-wave operation at room temperature.

A number of aspects of the present invention provide beneficial VCSEL fabrication and operational benefits. The device incorporates a high contrast grating (HCG) as a top mirror on a InP-based VCSEL emitting at 1.55 μm. It should be appreciated that although an embodiment of the invention is described for operation at 1.55 μm, the teachings of the present invention can be utilized for fabricating VCSELs operating across a range of wavelengths, such as preferably any wavelength between 1.3 μm and 2.2 μm, as well as between 0.85 μm to 1 μm and also in the wavelengths between about 1.6 μm to 2.3 μm. The current aperture is preferably formed by utilizing a hydrogen ion implantation process near the active region, providing a planar process without the need of a second epitaxy growth. A tunnel junction is preferably utilized near the active region, on what would otherwise be the p-side of the wafer, for removing the majority of the p-doped materials. The HCG structure itself is preferably processed by chemical etching (i.e., wet or dry), allowing high throughput and low cost fabrication. These teachings can be implemented separately, or more preferably, in various combinations with one another.

The high contrast grating provides a high degree of polarization differentiation, so VCSELs with HCGs do not have degenerate polarization modes, which is very undesirable for telecommunications applications. In addition, the HCG provides transverse mode selectivity, leading to the creation of single-transverse-mode lasers having larger apertures, higher power outputs and improved coupling with optical fibers.

The HCG can be appropriately doped to form an additional electrically-blocking junction on top of the tunnel junction, leading to a micro-electro-mechanically tunable VCSEL. Alternatively to a tunable VCSEL, an array of VCSELs with a fixed wavelength spacing for CWDM applications can be created by varying the air gap depth underneath the HCG to achieve wavelength variation, while keeping the rest of the structure constant. The HCG structures can be configured for providing optical focusing for output coupling as well as providing optical confinement for the active region to increase optical efficiency. In a preferred implementation, the VCSEL is monolithically grown providing for simple fabrication which has substantial potential for lowering manufacturing cost in comparison to other long-wavelength VCSEL approaches.

Accordingly, the present invention includes a number beneficial structural and methodological elements. The device utilizes a high contrast grating (HCG) as a top mirror on a VCSEL, such as an InP-based VCSEL emitting at 1.55 μm, although the method can be utilized to fabricate VCSELS of any wavelength between approximately 0.85 μm and 2.3 μm. The current aperture is formed by a hydrogen ion implantation process near the active region, providing a planar process without the need of a second epitaxy growth. A tunnel junction is incorporated near the active region on what would be otherwise be the p-side of the wafer, for removing the majority of p-doped materials. The HCG structure can be processed by wet or dry chemical etching, allowing high throughput and low cost fabrication. The high contrast grating provides a high degree of polarization differentiation, so VCSELs with HCGs do not have degenerate polarization modes, which is very undesirable for telecommunications applications. In addition, the VCSEL device provides transverse mode selectivity, leading to single mode lasers with larger aperture, higher power and better coupling with optical fibers. The HCG can be appropriately doped to form an additional p-n junction on top of the tunnel junction, leading to micro-electro-mechanically tunable VCSEL. The air gap depth underneath the HCG can also be varied to achieve wavelength variation and thus a multiwavelength VCSEL array with controllable wavelength spacing. The HCG can be designed to provide optical focusing for output coupling as well as providing optical confinement for the active region to increase optical efficiency. The VCSEL is monolithically grown, simple to fabricate, and represent a significant potential for lowering manufacturing cost over in relation to other long wavelength VCSEL approaches.

The invention is amenable to being embodied in a number of ways, including but not limited to the following descriptions.

One embodiment of the invention is an apparatus for surface emission of light amplification by stimulated emission of radiation from a vertical cavity, comprising: (a) a first mirror; (b) an active layer disposed over the first mirror and having a plurality of quantum wells configured for laser light generation; (c) an electrical confinement layer disposed over the active region; (d) a vertical resonator cavity disposed over, or under, the electrical confinement layer; and (e) a high-contrast grating (HCG) operating as a second mirror disposed over the vertical resonator cavity for reflecting a first portion of the light back into the vertical resonator cavity at a controlled polarization, while a second portion of the light is output from the apparatus. Preferred implementations are based on Indium Phosphide (InP) and implemented to provide output emissions in the wavelength range from approximately 1.3 μm to 1.6 μm, as well as between about 0.85 μm to 1 μm and in the wavelengths between approximately 1.6 μm to 2.3 μm.

In at least one implementation, a tunnel junction is disposed over the active layer for removing the majority of p-doped materials. In at least one implementation the electrical confinement layer comprises an area of ion implantation (e.g., protons) surrounding an aperture having a desired aperture width. In at least one implementation, the HCG provides optical confinement by acting as a lens. In at least one implementation, the high-contrast grating (HCG) is selected from a group of semiconductor materials consisting of Indium Phosphide (InP), InGaAlAs, or GaAlAs. In at least one implementation, the body of the VCSEL largely comprises Indium Phosphide (InP). In at least one implementation the VCSEL further comprises an electrical conduction layer (e.g., heat sinking) disposed between the first mirror and the active region.

In at least one implementation, the VCSEL further comprises a micro-mechanical actuator coupled to the high-contrast grating (HCG). The HCG is movably retained over the vertical resonator cavity so that the length of the vertical resonator cavity is changed, which alters resonant wavelength and the second portion of the light which is output, in response to one or more actuation levels of the micro-mechanical actuator. In at least one implementation, the micro-mechanical actuator comprises an electrostatic force actuator which is actuated in response to an applied voltage level, and/or a thermal actuator which is actuated in response to an applied current.

In at least one implementation, the HCG provides optical confinement by acting as a lens. This lensing action is derived from optical phase variation which arises in response to non-uniform grating spacing, thus providing optical focusing of the light interacting with the HCG.

In at least one implementation, a sacrificial layer is disposed between the high-contrast grating (HCG) and the electrical confinement layer. Vertical resonator depth and wavelength of the VCSEL are determined in response to the extent to which the sacrificial layer is removed in the direction orthogonal to the surface of the sacrificial layer, which is adjacent to the high-contrast grating (HCG).

One embodiment of the invention is an apparatus for surface emission of light amplification by stimulated emission of radiation from a vertical cavity, comprising: (a) a first mirror; (b) an active layer disposed over the first mirror and having a plurality of quantum wells configured for laser light generation; (c) an electrical confinement layer disposed over the active region with ion implantation surrounding an aperture having a desired aperture width; (d) a vertical resonator cavity disposed over the electrical confinement layer; and (e) a high-contrast grating (HCG) operating as a second mirror disposed over the vertical resonator cavity for reflecting a first portion of the light back into the vertical resonator cavity at a controlled polarization, while a second portion of the light is output from the apparatus. In at least one implementation, a tunnel junction disposed over the active layer for removing the majority of p-doped materials.

One embodiment of the invention is an apparatus for surface emission of light amplification by stimulated emission of radiation from a vertical cavity, comprising: (a) a first mirror; (b) an electrical conduction layer disposed over the first mirror; (c) an active layer disposed over the electrical conduction layer and having a plurality of quantum wells configured for laser light generation; (d) a tunnel junction disposed over the active layer for removing the majority of p-doped materials; (e) an ion implantation region surrounding an aperture area having a desired aperture width; (f) a vertical resonator cavity disposed over the tunnel junction; and a high-contrast grating (HCG) operating as a second mirror disposed over the vertical resonator cavity for reflecting a first portion of the light back into the vertical resonator cavity at a controlled polarization, while a second portion of the light is output from the apparatus. In at least one implementation, the high-contrast grating (HCG) provides optical confinement by operating as a lens. In at least one implementation the HCG is fabricated from Indium Phosphide, although it can be alternatively fabricated from InGaAlAs, GaAlAs, or similar semiconductor materials. The VCSEL and its HCG are based on InP in preferred implementations and are configured for output emissions in the 1.3 μm to 1.6 μm wavelength range. It should be appreciated that VCSELs can be fabricated according to the invention in bordering wavelength ranges, such as between about 0.85 μm to 1 μm and 1.6 μm to 2.3 μm.

In at least one implementation, the VCSEL further comprises a micro-mechanical actuator coupled to the high-contrast grating (HCG) whose actuation level controls the resonant wavelength to alter the wavelength of the second portion of the light which is output. The HCG is movably retained over the vertical resonator cavity, so that the actuator can change its position to alter the depth of the vertical resonator cavity in response to one or more actuation levels of the actuator. It will be appreciated that any desired form of actuator can be used in the embodiments of the invention, and are particularly well-suited for use of electrostatic force actuators which actuated in response to an applied voltage level, and/or thermal actuators which are actuated in response to an applied current.

One embodiment of the invention is a method for fabricating a high contrast grating (HCG) within a VCSEL, comprising: (a) depositing a sacrificial layer over a vertical cavity area within the body of a vertical cavity surface emitting laser structure; depositing a grating layer over the sacrificial layer; (b) depositing an epitaxial hard mask layer over the grating layer; (c) depositing a resist layer over the epitaxial hard mask layer; removing portions of the resist layer down to the epitaxial hard mask layer to define a pattern for a high contrast grating (HCG); (d) etching (e.g., wet or dry etching) of the epitaxial hard mask layer, under controlled temperature conditions, down to the grating layer to define the pattern of the HCG in the epitaxial hard mask; (e) transferring the pattern of the HCG by wet etching away portions of the grating layer through the epitaxial hard mask with a crystalline dependent wet etch yielding vertical sidewalls; (f) selective etching away of the sacrificial layer underneath the HCG to release the HCG and leave an air gap between the HCG and the vertical cavity area within the body of the VCSEL. In at least one implementation, etching of the grating layer is performed by a crystal plane selective etch which is performed under controlled temperature and PH. In at least one implementation, the extent of removal of the sacrificial layer, in a direction orthogonal to its surface and adjacent to the HCG, determines vertical resonator cavity depth and VCSEL wavelength.

The present invention provides a number of beneficial elements which can be implemented either separately or in any desired combination without departing from the present teachings.

An element of the invention is a VCSEL utilizing a high contrast grating (HCG) as the upper mirror.

Another element of the invention is a VCSEL having an HCG as the upper mirror and which can be fabricated from Indium Phosphide (InP).

Another element of the invention is a VCSEL having an HCG upper mirror which also acts as a lens to provide optical confinement.

Another element of the invention is a VCSEL having an HCG upper mirror and capable of operating at wavelengths at or above approximately 0.85 μm and more preferably in the long-wavelength range above 1.3 μm.

Another element of the invention is a VCSEL having a tunnel junction over the active layer.

Another element of the invention is a VCSEL with an HCG upper mirror in which current confinement is provided in response to ion implantation (e.g., implanting protons) surrounding an aperture.

Another element of the invention is a VCSEL with HCG upper mirror that incorporates a an electrical conduction layer below the active layer.

Another element of the invention is a VCSEL with an HCG upper mirror whose position can be modulated to alter resonant cavity depth in response to the extent of actuation of a micro-mechanical actuator.

Another element of the invention is a VCSEL with an HCG upper mirror in which the micro-mechanical actuator couple to said HCG is an electrostatic force actuator, or a thermal actuator.

Another element of the invention is a method of fabricating a high contrast grating, in particular within a VCSEL structure or similar.

Another element of the invention is a method of fabricating a high contrast grating (HCG) within a VCSEL utilizing an epitaxial hard mask and wet etching to transfer the HCG pattern to the HCG layer.

Another element of the invention is a method of fabricating a high contrast grating (HCG) within a VCSEL by etching away portions of the HCG layer utilizing a crystal plane selective etch.

Another element of the invention is a method of fabricating a high contrast grating (HCG) within a VCSEL by etching away all, or any desired portion, of a sacrificial layer beneath the HCG layer to define vertical cavity depth beneath the HCG, and thus control optical wavelength.

Another element of the invention is a VCSEL with an HCG upper mirror formed by utilizing wet etching performed under controlled temperature and PH.

A still further element of the invention is the fabrication of a VCSEL which can be utilized in a wide variety of applications, including metro area access networks, PON applications, and diode laser spectroscopy.

Further elements of the invention will be brought out in the following portions of the specification, wherein the detailed description is for the purpose of fully disclosing preferred embodiments of the invention without placing limitations thereon.

### BRIEF DESCRIPTION OF THE SEVERAL VIEWS OF THE DRAWING(S)

The invention will be more fully understood by reference to the following drawings which are for illustrative purposes only:

FIG. 1 is a cross-sectional schematic diagram of a 1550 nm VCSEL according to an embodiment of the present invention.

FIG. 2 is a schematic of a high contrast grating (HCG) according to elements of the present invention.

FIG. 3A through 3D are graphs of the reflectivity of HCG and air gap as measured from the active region as a function of duty cycle with respect to wavelength in FIG. 3A, air-gap width with respect to period in FIG. 3B, HCG thickness with respect to wavelength in FIG. 3C, and sacrificial layer thickness with respect to wavelength in FIG. 3D.

FIG. 4A through 4D are schematics of fabrication flow for a high contrast grating according to elements of the present invention.

FIG. 5A through 5C are images of a HCG VCSEL according to elements of the present invention.

FIG. 6A through 6B are graphs of light current characteristics of a device according to elements of the present invention.

FIG. 7 is a cross-sectional schematic diagram of a tunable VCSEL structure according to elements of the present invention.

FIG. 8A through 8C are cross-sectional schematic diagrams of a tunable VCSEL according to elements of the present invention.

FIG. 9A through 9D are schematic diagrams of tunable VCSELs according to elements of the present invention.

FIG. 10A through 10D are schematic diagrams of multiwavelength HCG VCSEL arrays according to the present invention, showing varying air gap depth in response to extent of vertical etching of sacrificial layer.

FIG. 11 is a schematic diagram of HCG lensing according to an element of the present invention.

FIG. 12 is a cross-sectional schematic diagram of a lensing HCG integrated on a VCSEL according to an element of the present invention.

### DETAILED DESCRIPTION OF THE INVENTION

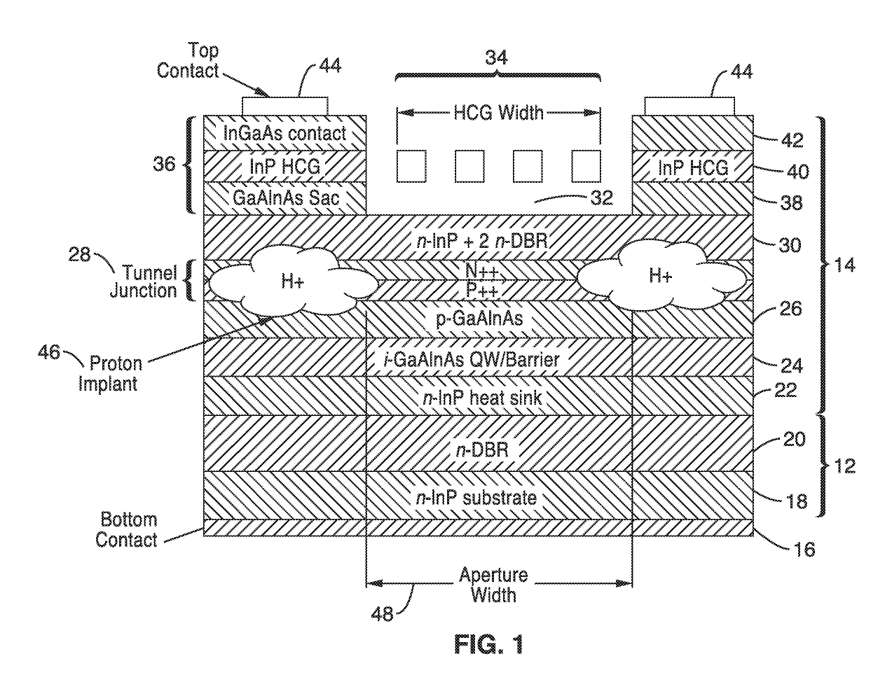

Referring more specifically to the drawings, for illustrative purposes the present invention is embodied in the apparatus generally shown in FIG. 1 through FIG. 12. It will be appreciated that the apparatus may vary as to configuration and as to details of the parts, and that the method may vary as to the specific steps and sequence, without departing from the basic concepts as disclosed herein. Furthermore, elements represented in one embodiment as taught herein are applicable without limitation to other embodiments taught herein, and combinations with those embodiments and what is known in the art.

1. Device Structure of HCG Integrated VCSEL.

FIG. 1 is an example embodiment 10 of a VCSEL, shown by way of example and not limitation for operating at 1550 nm. The VCSEL 10 comprises a substrate portion 12, and active portion 14. In the substrate section 12 is an n-InP substrate 18, under which is a contact 16. Above the substrate is a mirror, preferably comprising a plurality of n-DBR layers 20 (e.g., 45 pairs), and preferably an electrical conduction layer 22, such as an InP electrical conduction layer (e.g., heat sink) as shown. The active portion 14 comprises an active region 24, preferably having a plurality of GaAlInAs quantum wells (e.g., 6 quantum wells) configured for laser light generation, and a thin layer of p-GaAlInAs 26 to provide for current spreading, followed by a tunnel junction 28 having at least one pair of N++ and P++ layers, forming a tunnel junction which allows for an ohmic junction between n and p materials, allowing for the removal of the majority of p-doped materials. Above the tunnel junction 28 are disposed several n-DBR 30 in this case, although these can be removed entirely or replaced with more or fewer mirrors, followed by an air gap 32 and an InP high contrast grating 34.

It should be appreciated that the HCG can be fabricated from materials other than InP, such as from InGaAlAs, GaAlAs, or similar materials, without departing from the teachings of the invention. By way of example, the grating described is 8-20 μm wide. The HCG 34 is seen etched from a series of HCG fabrication layers 36, shown intact on either side of the HCG, comprising a sacrificial GaAlInAs layer 38, an InP HCG layer 40, and a contact layer 42, preferably comprising an epitaxial hard mask layer, such as of InGaAs. Top contacts 44 are shown disposed on the top of the device structure surrounding the HCG. It should be appreciated that reference herein to a “layer” does not limit the invention to a single physical layer, as the term can refer to a single layer in regards to a deposition or other formation process, or a layer in regards to its functionality which could be implemented with any desired number of physical deposition layers.

Electrical confinement is provided in the structure in response to an ion implantation 46, preferably proton implantation, at a depth near tunnel junction 28. It will be noted that electrical confinement reduces the threshold current of a VCSEL device by limiting the cross-sectional area in which gain occurs. In this example, the size of the proton implant aperture is preferably in the range of 8-20 μm. Aperture width 48 is depicted in the figure between proton implantations in the tunnel junction.

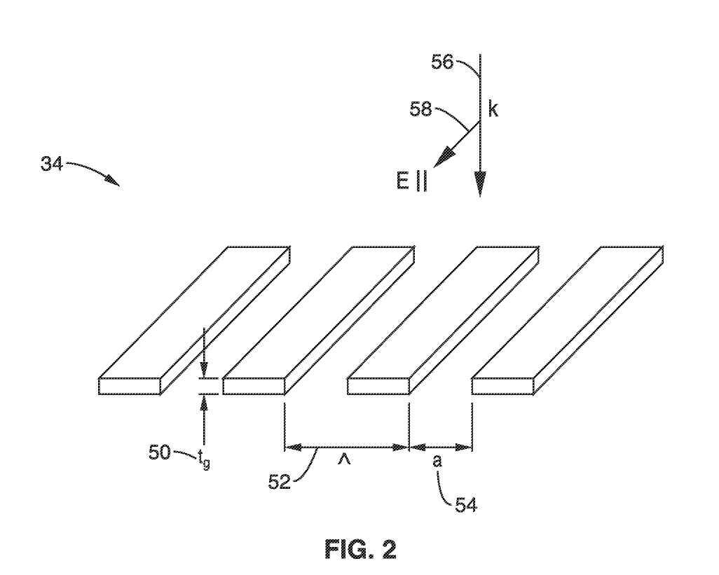

FIG. 2 illustrates an example embodiment of HCG 34 within the VCSEL embodiment of FIG. 1. By way of example and not limitation, the grating thickness t_{g} 50 is 195 nm, period Λ52 is approximately 1070 nm, and air gap a 54 is approximately 700 nm. The HCG is configured for reflecting light k at incidence 56 with the electric field E polarized parallel 58 to the direction of the grating bars. The grating is designed to reflect light at high efficiency with the electric field polarized parallel to the direction of the grating bars, but to have limited reflectance in response to the orthogonal polarization. The grating is preferably optimized to provide a wide tolerance to air-gap dimensions, whereby etching of the epitaxial hard mask, as described in a later section on fabrication, can have significant errors (e.g., such as by as much as 150 nm) from the design center while maintaining proper device operation.

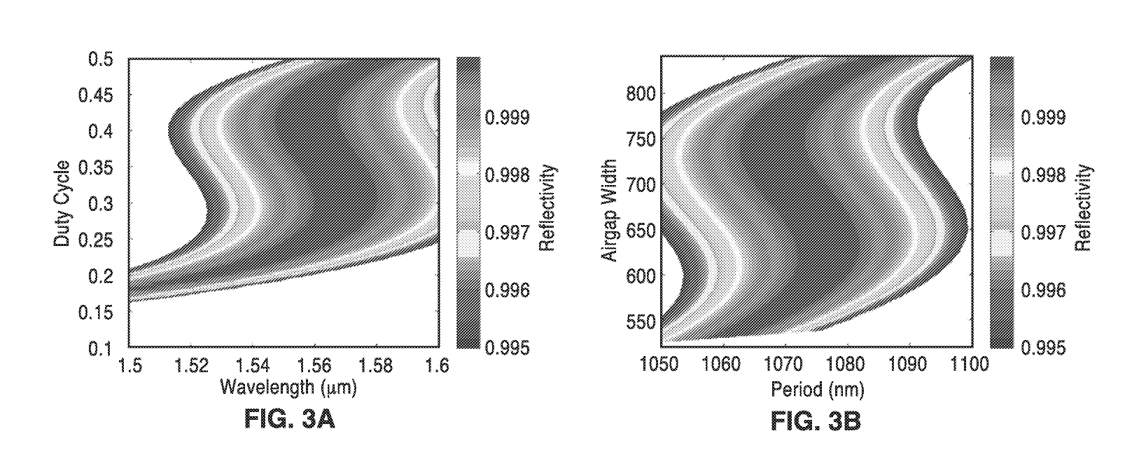

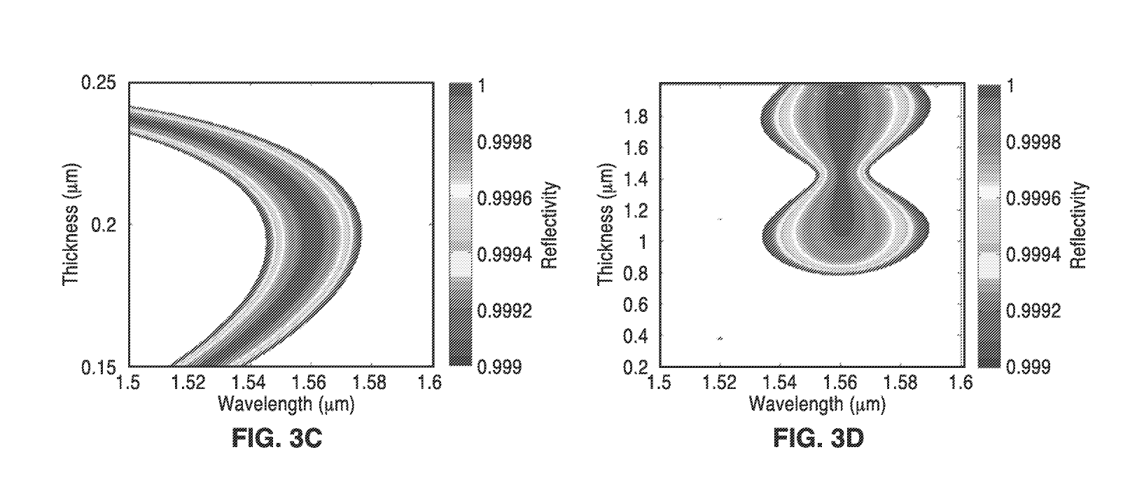

FIG. 3A through FIG. 3D depict HCG reflectivity as measured from the active region as a function of duty cycle with respect to wavelength in FIG. 3A, air gap width with respect to period in FIG. 3B, in response to HCG thickness with respect to wavelength in FIG. 3C, and in response to sacrificial layer thickness with respect to wavelength in FIG. 3D. In this test, the other parameters were held fixed with a grating thickness at 195 nm, an HCG period of 1075 nm, a grating bar width (DC) of 35% (˜375 nm of grating bar and ˜700 nm interbar air-gap spacing), an air gap thickness of 1.83 μm (sacrificial layer thickness), which exhibits a center wavelength of 1.56 μm. The HCG material in this example embodiment comprises InP with a refractive index of 3.17.

2. Fabrication Process.

According to a preferred process VCSEL device fabrication was carried out according to the following general steps. A backside n-contact was first uniformly evaporated onto the substrate. The current injection aperture was protected by a thick layer of photoresist (e.g., exceeding 7 μm thick), followed by H ion implantation with a dosage between 10¹⁴ cm⁻² to 10¹⁵ cm⁻² and using a level of energy between 250 keV to 400 keV. A top annular n-contact was subsequently fabricated by lithography, metal evaporation and lift-off. A mesa was non-selectively etched, such as by a Bromine-based etchant, to electrically isolate the devices from each other.

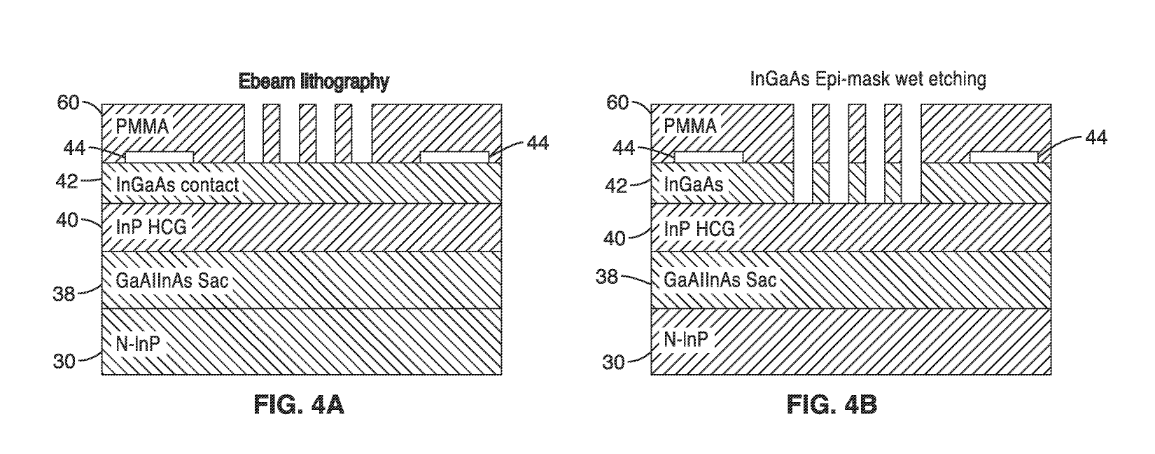

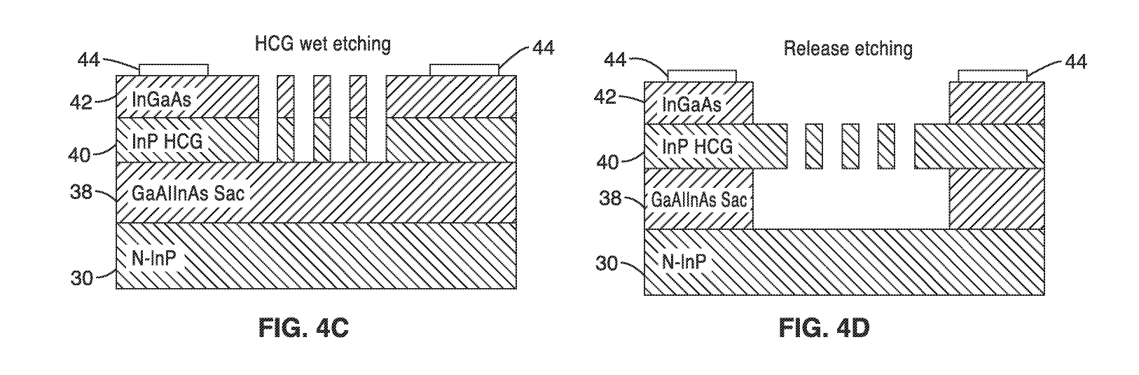

FIG. 4A through FIG. 4D illustrate HCG definition and release using wet etch only. As shown in FIG. 4A a resist 60 (e.g., PMMA) was applied over the VCSEL body layers, in preparation for defining the HCG by electron beam lithography. It will be noted that the same layer numbers in FIG. 4A through FIG. 4D refer to the same layer compositions as shown in FIG. 1. Wet etching was performed in FIG. 4B to transfer the pattern to epitaxial hard mask layer, which doubles as the contact layer. It should be appreciated that the pattern can be alternatively defined using a standard DUV lithography stepper, or other mechanisms as desired. An InGaAs epitaxial hard mask is first wet etched in a temperature-controlled etch process, such as using a sulfuric acid-based etchant retained in an ice bath. An epitaxial hard mask is necessary because of its excellent adhesion to the HCG layer. In FIG. 4C the pattern is transferred to the InP layer by a crystalline dependent wet etch which yields vertical sidewalls. The wet etch for example comprises a temperature controlled HCl-based etchant (e.g., retained in an ice bath). This etch process is highly crystal plane selective, so that when the HCG is properly aligned to the substrate, extremely straight vertical sidewalls are transferred into the InP as defined by the epitaxial hard mask. Subsequently, as shown in FIG. 4D the HCG is released by another wet etch, which etches the sacrificial layer and contact layer but not the HCG, and leaves the high index HCG suspended from the substrate.

It should be appreciated that any desired portion, or all, of the sacrificial layer adjacent the HCG can be removed for selecting the depth of the resonator cavity and thus the operating frequency of the final VCSEL device. The removal of the sacrificial layer is considered in relation to a direction that is orthogonal to the plane of the sacrificial layer. Stated another way, the depth and wavelength of the vertical resonator is determined in response to the extent of removal of the sacrificial layer, in a direction orthogonal to the surface of the sacrificial layer, which is adjacent to the high-contrast grating (HCG).

In principle, this HCG fabrication process can be performed using any desired material system where a crystalline dependent etch can be performed on the HCG material and in which a strongly selective etch is performed to release the HCG and remove the epitaxial hard mask at the same time while not adversely affecting the HCG.

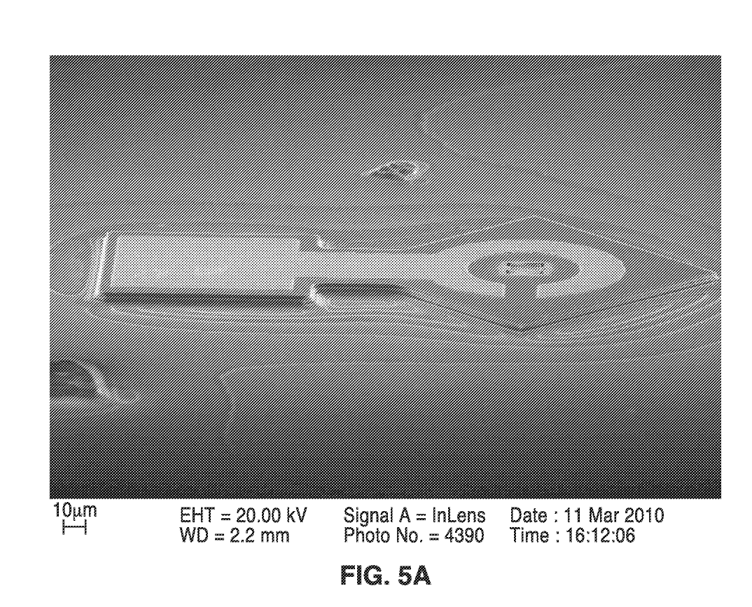

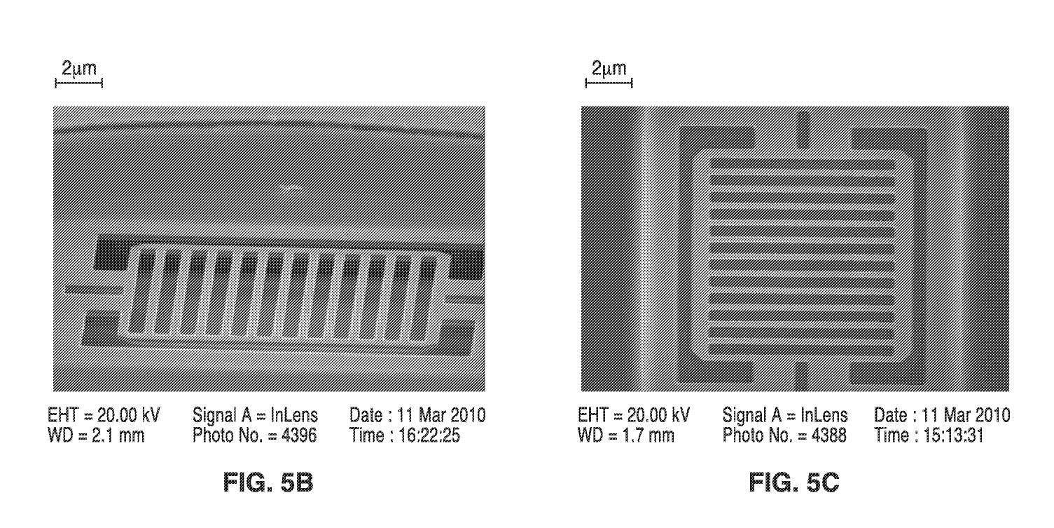

FIG. 5A through FIG. 5C are SEM images of an HCG VCSEL fabricated according to the fabrication method according to the present invention. In FIG. 5A the entire device is shown with the fabricated HCG at the center of the C-shaped portion of the top electrode. A first and second view of the HCG are shown in FIG. 5B and FIG. 5C.

3. Experimental Results.

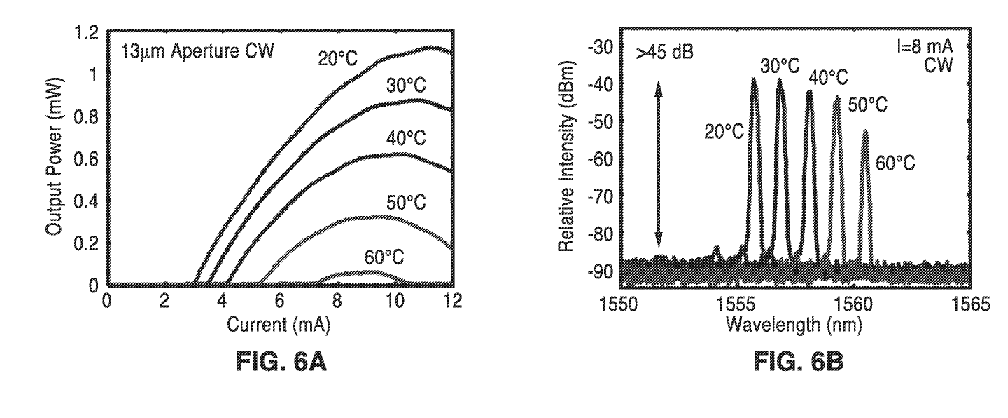

FIG. 6A through FIG. 6B depict characteristics of the VCSEL device which was shown in FIG. 5A through FIG. 5C. Devices fabricated according to the invention have been shown to provide excellent optical characteristics with a peak output power at room temperature of greater than 1 mW and slope efficiencies of greater than 0.25 mW/mA. Current and wavelength characteristics are shown with respect to temperature in FIG. 6A through FIG. 6B. The device lases at temperatures below 60° C., with lasing curves shown in FIG. 6A at temperatures from 20° C. to 60° C. depicted in 10° C. steps. The lasing threshold at room temperature occurs at about 3 mA. The device is lasing at around 1555 nm, with an optical spectrum in response to a constant current of 8 mA and varying operating temperatures shown in FIG. 6B. From the graph a temperature-dependent wavelength shift can be seen of 0.12 nm/K.

4. Tunable VCSEL Structure.

The VCSEL structure described can be readily modified into a tunable VCSEL which can provide a number of benefits in various application areas, such as for use in wavelength division multiplexed (WDM) access networks and passive optical networks (PON). This change can be readily implemented by moving the laser contact to below the sacrificial layer, adding a current blocking junction, and adding a tunable mechanical actuator structure for controlling the gap between the HCG and the body of the structure, which results in tuning of the resonant cavity of the laser, and thus its output wavelength.

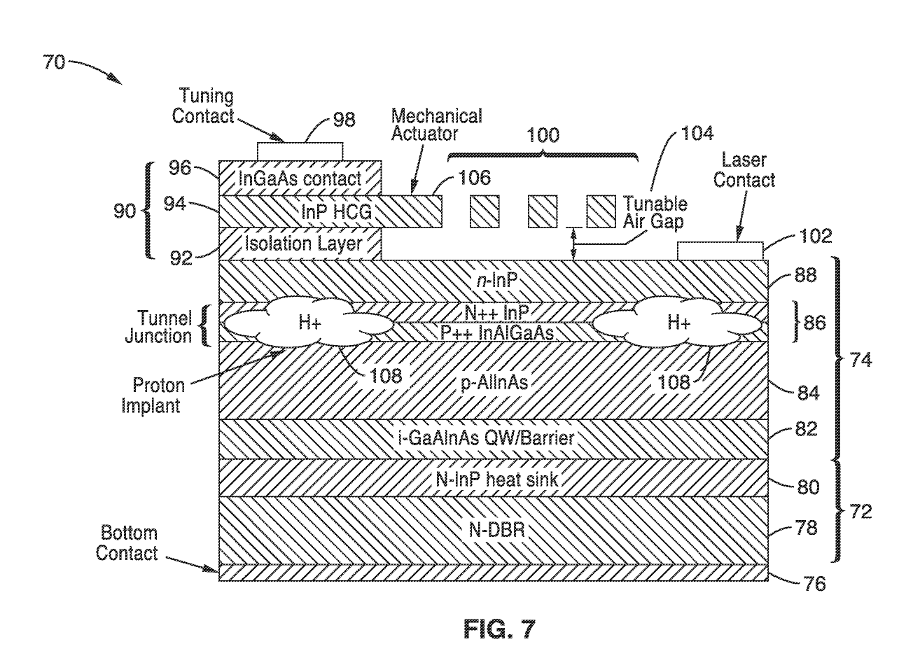

FIG. 7 illustrates an example embodiment 70 of a tunable VCSEL structure according to the invention with inactive substrate portion 72 and active portions 74. Under a substrate 78 comprising an N-DBR layer section is seen a bottom contact 76, above which is at least one N-InP electrical conduction (e.g., heat sink) layer 80. The active layers 74 comprise an active region 82 of i-GaAlInAs with a plurality of quantum well. A layer of p-AlInAs 84 is shown followed by a tunnel junction 86 having one pair of N++ (e.g., InP) and P++ (e.g., InAlGaAs) layers. Ion implantation 108 is shown, such as preferably utilizing proton implantation, at a depth near the tunnel junction. Above tunnel junction 86 is disposed an n-InP layer 88, above which are the layers 90 from which the HCG is formed, shown comprising a sacrificial isolation layer 92, an InP HCG layer 94, and a sacrificial InGaAs contact layer 96. The current blocking junction is shown comprising isolation layer 92 used as the sacrificial layer comprises an insulator (e.g., dielectric) to prevent current leakage between the tunable mechanical section and the laser contact. A tuning contact 98 is shown adjacent the freed HCG structure 100, which can be performed as described with regard to FIG. 4A through FIG. 4D. The laser contact 102 is disposed on the top layer directly above the cavity, such as the InP layer as shown, or an InGaAs contact layer.

It can be seen in the figure that the HCG structure 100 is configured to allow for movement between it and the resonant cavity structure. In the example shown, the HCG structure is configured in a cantilevered arrangement to provide this adjustment of tuning air gap 104, although it should be appreciated that a wide variety of structures can be adopted, without limitation, that provide the ability to mechanically deflect. Deflection of the HCG in relation to the vertical cavity is performed in response to controlling a mechanical actuator, such as one operating in response to electrostatic effects when a voltage is applied to the HCG in relation to the device body voltage beneath isolation layer 92.

In the described implementation, a voltage applied between laser contact 102 and top tuning contact 98, results in the generation of an electrostatic force which pulls HCG 100 toward the body of the VCSEL, reducing the air gap and changing device tuning with its associated output wavelength. It should be appreciated that the micro-mechanical actuator can be configured for controlling mechanical deflection by any desired means, with preferred implementations configured to operate in response to electrostatic force actuation and/or thermal actuation. As an example of thermal actuation, a current can be passed through the mechanical structure supporting the HCG, causing them to heat and expand, and thus resulting in movement of the HCG with respect to the body of the VCSEL.

5. Current Blocking.

It should be recognized that although depicted as an electrically insulating layer in the previous example, the current blocking junction can be implemented in various ways to prevent current leakage into the body of the structure.

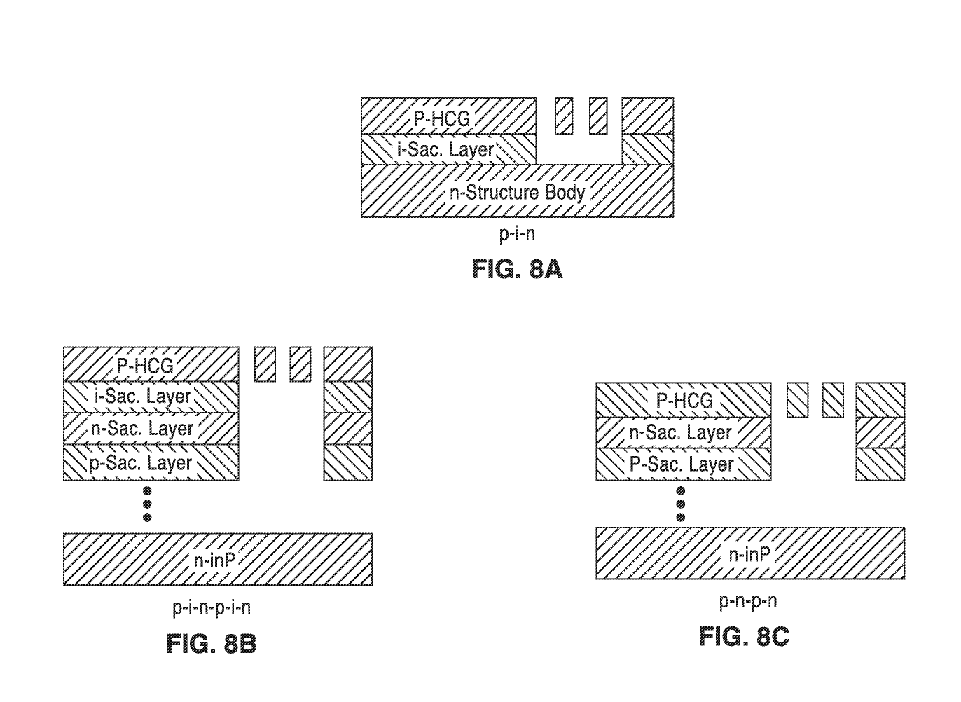

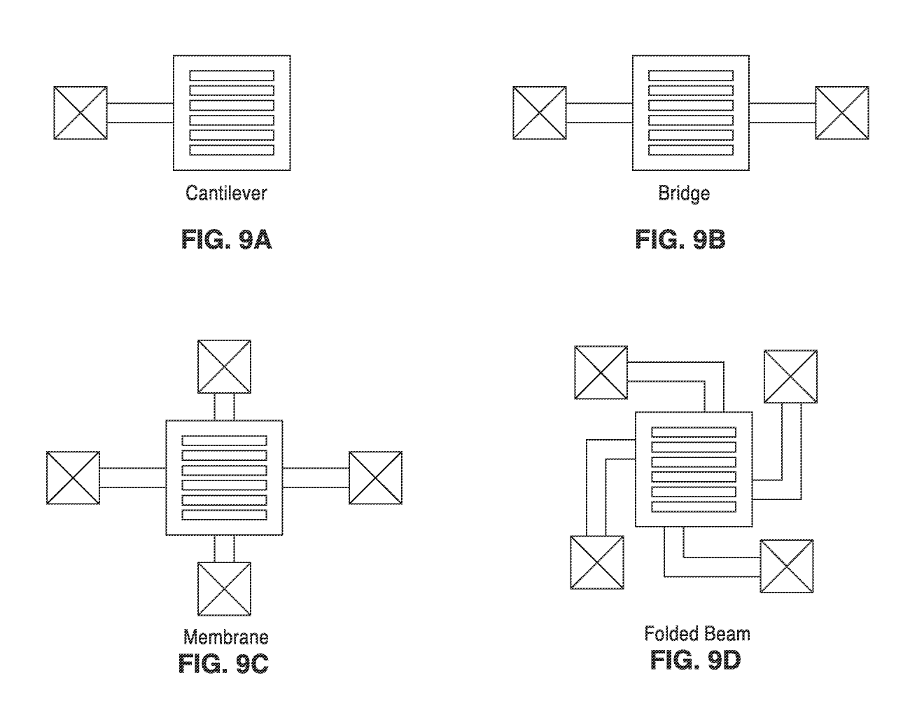

FIG. 8A through FIG. 8C illustrate alternative embodiments of blocking structures which use various material combinations. The blocking structure can comprise various combinations of p, i, and n materials, such as series combination of p-n or p-i-n junctions which are subject to reverse biasing during the tuning operation to prevent current leakage into the laser body. FIG. 8A depicts a p-i-n blocking junction, while FIG. 8B shows a p-i-n-p-i-n blocking junction, and FIG. 8C a p-n-p-n type blocking junction.

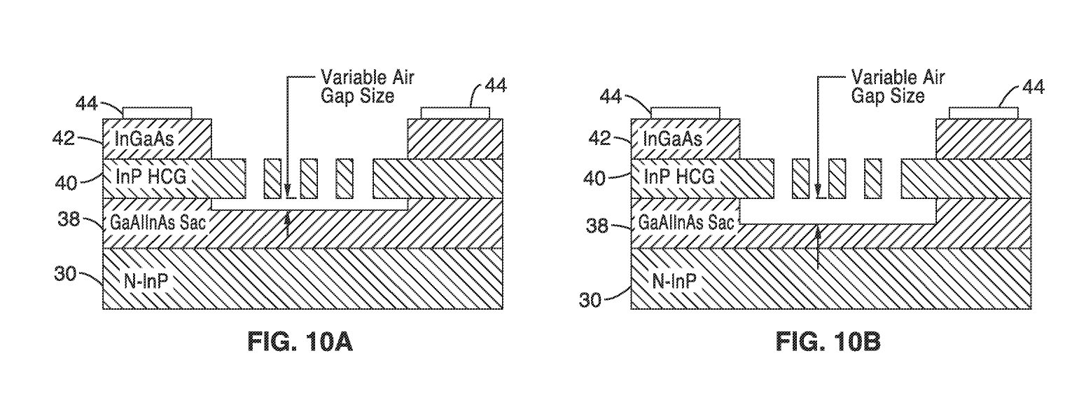

FIG. 9A through FIG. 9D illustrate different configurations of MEMS actuator structures as a cantilever in FIG. 9A, a bridge in FIG. 9B, a membrane in FIG. 9C, and a folded beam in FIG. 9D. It will be appreciated that a wide variety of mechanical deflection means can be utilized, such as micro-electro-mechanical structures (MEMS), without departing from the teachings of the present invention.

6. Multiwavelength HCG VCSEL Array.

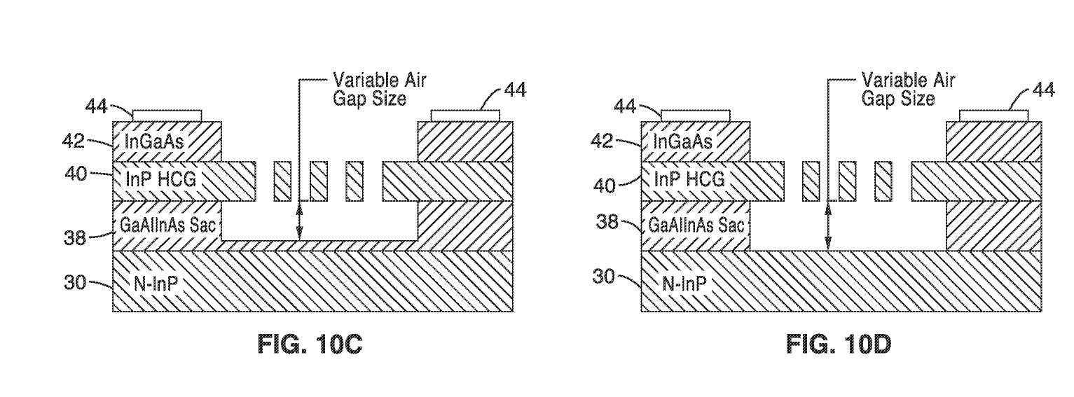

FIG. 10A through FIG. 10D illustrate embodiments with multiwavelength array structure having a n-DBR 30 layer, a sacrificial layer 38, HCG layer 40, contact or hard mask layer 42 and a contact 44. The figure depicts etching of the sacrificial layer 38 to different vertical extents in each of the implementations shown. Similar reference numbers designating similar compositions as discussed in previous figures. FIG. 10A depicts a small portion of the sacrificial layer etched away, while FIGS. 10B and 10C depict intermediate levels of etching, and in FIG. 10D the entire sacrificial layer beneath the HCG have been etched away. Wavelength variation across the structure is achieved by varying the air gap size underneath the HCG. The optical path length between the two mirrors, one of which is the bottom DBR and other is the HCG, determines lasing wavelength. Devices with shallower air gaps have more high index semiconductor in the cavity than those with a deeper air gap. Accordingly, devices with more shallow wavelengths have a longer optical path in the cavity and will then emit on a redder wavelength. The wavelength range achievable by this method is limited by the gain spectrum of the VCSEL active region.

7. Optical Confinement Using a HCG.

Ion implantation is not typically the method of choice for confining current in VCSELs due to the lack of a strong transverse optical confinement to the cavity. Typically, an ion-implanted aperture relies on thermal lensing to provide a measure of optical confinement. This leads to a relatively high threshold current compared to other types of current confinement. Additionally, using thermal lensing as optical confinement is well known to hinder high speed modulation of VCSELs.

However, in response to using an HCG as a top mirror, an alternative form of optical confinement is provided in an ion-implanted VCSEL, because the HCG can also provide optical confinement. The HCG provides optical confinement by acting as a lens.

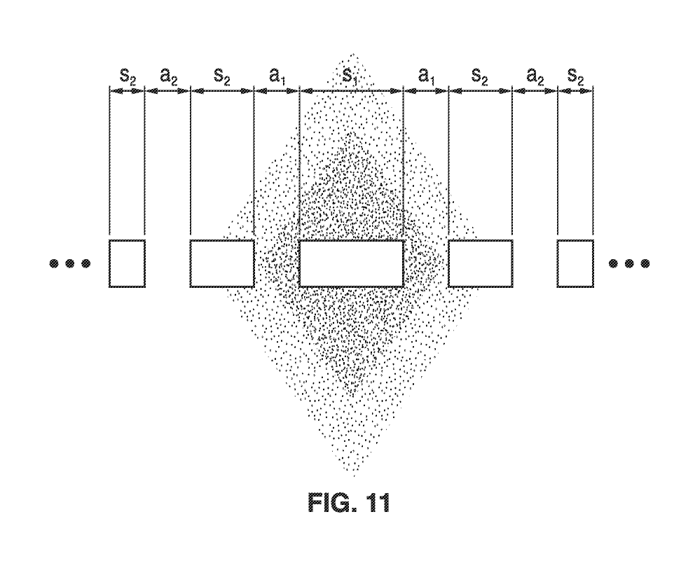

FIG. 11 depicts lensing of an HCG with phase variation achieved across the structure by varying the HCG semiconductor widths (s₁, s₂) and air widths (a₁, a₂). This phase variation is achieved by tailoring the phase response across the face of the HCG by changing the duty cycle and period, as shown in the figure. If this phase response is designed properly, the HCG will focus the light back on the aperture. In addition, the transmitted wave will also be focused due to the phase relation that exists between the reflection and transmission in a lossless two-port system. By fabricating this lensing HCG on a VCSEL, optical confinement is provided, whereby thermal lensing is not necessary.

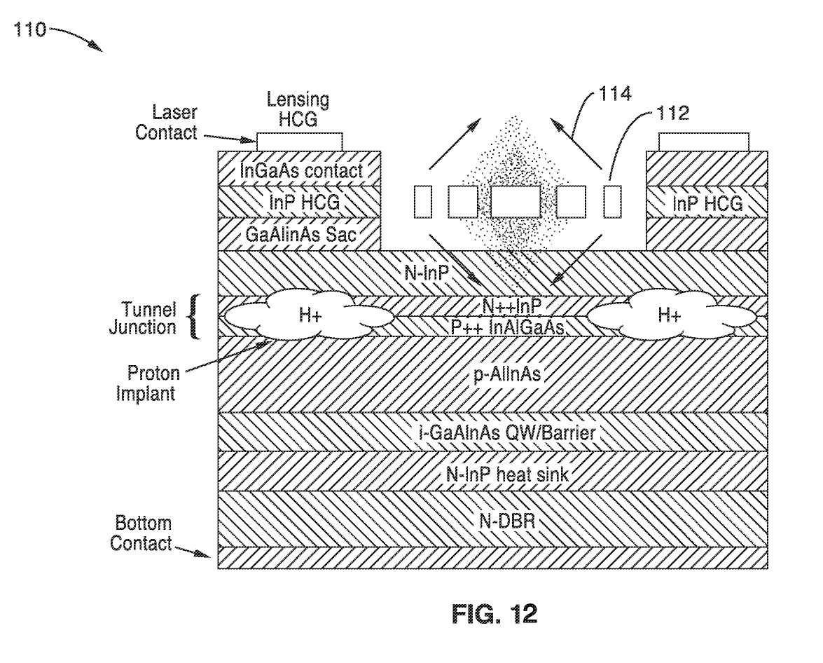

FIG. 12 illustrates an example embodiment 110 of a lensing HCG integrated on a VCSEL, which is similar to that shown in FIG. 7. An HCG 112 is depicted in the VCSEL which is configured with selected material widths and gap widths to redirect 114 the light, as also shown in FIG. 11, to provide the desired lensing. Using an HCG lens in combination with an ion implanted long wavelength VCSEL can provide a high speed, low cost source for next generation optical networks.

As can be seen, therefore, the present invention provides methods and apparatus for vertical emission of laser light in a VCSEL incorporating a high contrast grating upper mirror. It will be appreciated that the present invention includes the following inventive embodiments among others:

1. An apparatus for surface emission of light amplification by stimulated emission of radiation from a vertical cavity, comprising: a first mirror; an active layer disposed over said first mirror and having a plurality of quantum wells configured for laser light generation; a tunnel junction disposed over said active layer for removing the majority of p-doped materials; an electrical confinement layer disposed over, or under, said active region; a vertical resonator cavity disposed over said electrical confinement layer; and a high-contrast grating (HCG) operating as a second mirror disposed over said vertical resonator cavity for reflecting a first portion of the light back into said vertical resonator cavity at a controlled polarization, while a second portion of the light is output from said apparatus.

2. The apparatus of embodiment 1, wherein said electrical confinement layer comprises ion implantation surrounding an aperture having a desired aperture width.

3. The apparatus of embodiment 1, wherein said ion implantation comprises proton implantation.

4. The apparatus of embodiment 1, wherein said high-contrast grating (HCG) provides optical confinement by acting as a lens.

5. The apparatus of embodiment 1: wherein said high-contrast grating (HCG) provides optical confinement by acting as a lens; wherein said HCG is configured for optical phase variation in response to non-uniform grating spacing to provide optical focusing of the light interacting with said HCG.

6. The apparatus of embodiment 1, wherein material for said high-contrast grating (HCG) is selected from a group of semiconductor materials consisting of Indium Phosphide (InP), InGaAlAs, or GaAlAs.

7. The apparatus of embodiment 1, further comprising an electrical conduction layer disposed between said first mirror and said active region.

8. The apparatus of embodiment 1, further comprising: a micro-mechanical actuator coupled to said high-contrast grating (HCG); wherein said HCG is movably retained over said vertical resonator cavity; and wherein the depth of the vertical resonator cavity is changed, to alter the resonant wavelength and the second portion of light which is output, in response to one or more actuation levels of said micro-mechanical actuator.

9. The apparatus of embodiment 8, wherein said micro-mechanical actuator comprises an electrostatic force actuator which is actuated in response to an applied voltage level.

10. The apparatus of embodiment 8, wherein said micro-mechanical actuator comprises a thermal actuator which is actuated in response to an applied current.

11. The apparatus of embodiment 1, wherein said apparatus comprises a vertical cavity surface emitting laser (VCSEL) configured for output emissions in the 0.85 μm to 2.3 μm wavelength range.

12. The apparatus of embodiment 1, wherein said apparatus comprises a vertical cavity surface emitting laser (VCSEL) fabricated from Indium Phosphide (InP).

13. The apparatus of embodiment 1, further comprising: a sacrificial layer disposed between said high-contrast grating (HCG) and said electrical confinement layer; wherein the depth and wavelength of said vertical resonator is determined in response to the extent of removal of said sacrificial layer, in the direction orthogonal to the surface of said sacrificial layer, which is adjacent to said high-contrast grating (HCG).

14. An apparatus for surface emission of light amplification by stimulated emission of radiation from a vertical cavity, comprising: a first mirror; an active layer disposed over said first mirror and having a plurality of quantum wells configured for laser light generation; an electrical confinement layer disposed over said active region with ion implantation surrounding an aperture having a desired aperture width; a vertical resonator cavity disposed over said electrical confinement layer; and a high-contrast grating (HCG) operating as a second mirror disposed over said vertical resonator cavity for reflecting a first portion of the light back into said vertical resonator cavity at a controlled polarization, while a second portion of the light is output from said apparatus.

15. The apparatus of embodiment 14, further comprising a tunnel junction disposed over said active layer for removing the majority of p-doped materials.

16. The apparatus of embodiment 14, wherein said apparatus comprises a vertical cavity surface emitting laser (VCSEL) fabricated from Indium Phosphide (InP) lattice matched materials.

17. The apparatus of embodiment 14, further comprising: a micro-mechanical actuator coupled to said high-contrast grating (HCG); wherein said HCG is movably retained over said vertical resonator cavity; and wherein the depth of the vertical resonator cavity is changed, to alter the wavelength of the second portion of the light which is output, in response to one or more actuation levels of said micro-mechanical actuator.

18. The apparatus of embodiment 17, wherein said micro-mechanical actuator comprises an electrostatic force actuator which is actuated in response to an applied voltage level.

19. The apparatus of embodiment 17, wherein said micro-mechanical actuator comprises a thermal actuator which is actuated in response to an applied current.

20. The apparatus of embodiment 14, wherein said ion implantation comprises proton implantation.

21. The apparatus of embodiment 14, further comprising: a sacrificial layer disposed between said high-contrast grating (HCG) and said electrical confinement layer; wherein the depth and wavelength of said vertical resonator is determined in response to the extent of removal of said sacrificial layer, in the direction orthogonal to the surface of said sacrificial layer, which is adjacent to said high-contrast grating (HCG).

22. A method for fabricating a high contrast grating (HCG) within a VCSEL, comprising: depositing a sacrificial layer over a vertical cavity area within the body of a vertical cavity surface emitting laser structure; depositing a grating layer over the sacrificial layer; depositing an epitaxial hard mask layer over the grating layer; depositing a resist layer over the contact layer; removing portions of the resist layer down to said contact layer to define a pattern for a high contrast grating (HCG); wet or dry etching of said epitaxial hard mask layer, under controlled temperature conditions, down to said grating layer to define the pattern of the HCG in the epitaxial hard mask; transferring the pattern of the HCG by wet etching away portions of said grating layer through said epitaxial hard mask with a crystalline dependent wet etch yielding vertical sidewalls; selective etching away of the sacrificial layer underneath the HCG to release the HCG and leave an air gap between the HCG and the vertical cavity area within the body of the VCSEL.

23. The method of embodiment 22, wherein said etching of said grating layer comprises a crystal plane selective etch which is performed under controlled temperature and PH.

24. The method of embodiment 22, wherein the extent of removal of the sacrificial layer, in a direction orthogonal to the surface of said sacrificial layer and which is adjacent to said high-contrast grating (HCG), determines vertical resonator cavity depth and VCSEL wavelength.

Although the description above contains many details, these should not be construed as limiting the scope of the invention but as merely providing illustrations of some of the presently preferred embodiments of this invention. Therefore, it will be appreciated that the scope of the present invention fully encompasses other embodiments which may become obvious to those skilled in the art, and that the scope of the present invention is accordingly to be limited by nothing other than the appended claims, in which reference to an element in the singular is not intended to mean “one and only one” unless explicitly so stated, but rather “one or more.” All structural, chemical, and functional equivalents to the elements of the above-described preferred embodiment that are known to those of ordinary skill in the art are expressly incorporated herein by reference and are intended to be encompassed by the present claims. Moreover, it is not necessary for a device or method to address each and every problem sought to be solved by the present invention, for it to be encompassed by the present claims. Furthermore, no element, component, or method step in the present disclosure is intended to be dedicated to the public regardless of whether the element, component, or method step is explicitly recited in the claims. No claim element herein is to be construed under the provisions of 35 U.S.C. 112, sixth paragraph, unless the element is expressly recited using the phrase “means for.”

What is claimed is:

1. An apparatus for surface emission of light amplification by stimulated emission of radiation from a vertical cavity, comprising:
a first mirror;
an active layer disposed over said first mirror and having a plurality of quantum wells configured for laser light generation;
a tunnel junction disposed over said active layer for removing the majority of p-doped materials;
an electrical confinement layer disposed over, or under, said active region;
a vertical resonator cavity disposed over said electrical confinement layer; and
a high-contrast grating (HCG) operating as a second mirror disposed over said vertical resonator cavity for reflecting a first portion of the light back into said vertical resonator cavity at a controlled polarization, while a second portion of the light is output from said apparatus.

2. The apparatus as recited in claim 1, wherein said electrical confinement layer comprises ion implantation surrounding an aperture having a desired aperture width.

3. The apparatus as recited in claim 1, wherein said ion implantation comprises proton implantation.

4. The apparatus as recited in claim 1, wherein said high-contrast grating (HCG) provides optical confinement by acting as a lens.

5. The apparatus as recited in claim 1:
wherein said high-contrast grating (HCG) provides optical confinement by acting as a lens;
wherein said HCG is configured for optical phase variation in response to non-uniform grating spacing to provide optical focusing of the light interacting with said HCG.

6. The apparatus as recited in claim 1, wherein material for said high-contrast grating (HCG) is selected from a group of semiconductor materials consisting of Indium Phosphide (InP), GaAlInAs, InGaAsP and AlGaAsSb.

7. The apparatus as recited in claim 1, further comprising an electrical conduction layer disposed between said first mirror and said active region.

8. The apparatus as recited in claim 1, further comprising:
a micro-mechanical actuator coupled to said high-contrast grating (HCG);
wherein said HCG is movably retained over said vertical resonator cavity; and
wherein the depth of the vertical resonator cavity is changed, to alter the resonant wavelength and the second portion of light which is output, in response to one or more actuation levels of said micro-mechanical actuator.

9. The apparatus as recited in claim 8, wherein said micro-mechanical actuator comprises an electrostatic force actuator which is actuated in response to an applied voltage level.

10. The apparatus as recited in claim 8, wherein said micro-mechanical actuator comprises a thermal actuator which is actuated in response to an applied current.

11. The apparatus as recited in claim 1, wherein said apparatus comprises a vertical cavity surface emitting laser (VCSEL) configured for output emissions in the 0.85 μm to 2.3 μm wavelength range.

12. The apparatus as recited in claim 1, wherein said apparatus comprises a vertical cavity surface emitting laser (VCSEL) fabricated from Indium Phosphide (InP).

13. The apparatus as recited in claim 1, further comprising:
a sacrificial layer disposed between said high-contrast grating (HCG) and said electrical confinement layer;
wherein the depth and wavelength of said vertical resonator is determined in response to the extent of removal of said sacrificial layer, in the direction orthogonal to the surface of said sacrificial layer, which is adjacent to said high-contrast grating (HCG).

14. An apparatus for surface emission of light amplification by stimulated emission of radiation from a vertical cavity, comprising:
a first mirror;
an active layer disposed over said first mirror and having a plurality of quantum wells configured for laser light generation;
an electrical confinement layer disposed over said active region with ion implantation surrounding an aperture having a desired aperture width;
a vertical resonator cavity disposed over said electrical confinement layer; and
a high-contrast grating (HCG) operating as a second mirror disposed over said vertical resonator cavity for reflecting a first portion of the light back into said vertical resonator cavity at a controlled polarization, while a second portion of the light is output from said apparatus.

15. The apparatus as recited in claim 14, further comprising a tunnel junction disposed over said active layer for removing the majority of p-doped materials.

16. The apparatus as recited in claim 14, wherein said apparatus comprises a vertical cavity surface emitting laser (VCSEL) fabricated from Indium Phosphide (InP) lattice matched materials.

17. The apparatus as recited in claim 14, further comprising:
a micro-mechanical actuator coupled to said high-contrast grating (HCG);
wherein said HCG is movably retained over said vertical resonator cavity; and
wherein the depth of the vertical resonator cavity is changed, to alter the wavelength of the second portion of the light which is output, in response to one or more actuation levels of said micro-mechanical actuator.

18. The apparatus as recited in claim 17, wherein said micro-mechanical actuator comprises an electrostatic force actuator which is actuated in response to an applied voltage level.

19. The apparatus as recited in claim 17, wherein said micro-mechanical actuator comprises a thermal actuator which is actuated in response to an applied current.

20. The apparatus as recited in claim 14, wherein said ion implantation comprises proton implantation.

21. The apparatus as recited in claim 14, further comprising:
a sacrificial layer disposed between said high-contrast grating (HCG) and said electrical confinement layer;
wherein the depth and wavelength of said vertical resonator is determined in response to the extent of removal of said sacrificial layer, in the direction orthogonal to the surface of said sacrificial layer, which is adjacent to said high-contrast grating (HCG).

22. A method for fabricating a high contrast grating (HCG) within a VCSEL, comprising:
depositing a sacrificial layer over a vertical cavity area within the body of a vertical cavity surface emitting laser structure;
depositing a grating layer over the sacrificial layer;
depositing an epitaxial hard mask layer over the grating layer;
depositing a resist layer over the contact layer;
removing portions of the resist layer down to said contact layer to define a pattern for a high contrast grating (HCG);
wet or dry etching of said epitaxial hard mask layer, under controlled temperature conditions, down to said grating layer to define the pattern of the HCG in the epitaxial hard mask;
transferring the pattern of the HCG by wet etching away portions of said grating layer through said epitaxial hard mask with a crystalline dependent wet etch yielding vertical sidewalls;
selective etching away of the sacrificial layer underneath the HCG to release the HCG and leave an air gap between the HCG and the vertical cavity area within the body of the VCSEL.

23. The method as recited in claim 22, wherein said etching of said grating layer comprises a crystal plane selective etch which is performed under controlled temperature and PH.

24. The method as recited in claim 22, wherein the extent of removal of the sacrificial layer, in a direction orthogonal to the surface of said sacrificial layer and which is adjacent to said high-contrast grating (HCG), determines vertical resonator cavity depth and VCSEL wavelength.
